(19) United States
(12) Patent Application Publication
(10) Pub. No.: US 2014/0116510 A1
(43) Pub. Date: May 1, 2014

(54) STRUCTURE FOR IMPROVING THERMAL STABILITY OF BULK HETEROJUNCTION SOLAR CELLS AND RELATED PHOTOVOLTAIC APPARATUS AND METHOD FOR MAKING THE SAME

(71) Applicant: INSTITUTE OF NUCLEAR ENERGY RESEARCH ATOMIC ENERGY COUNCIL, EXECUTIVE YUAN, TAOYUAN COUNTY (TW)

(72) Inventors: CHENG-SI TSAO, Taoyuan County (TW); LEE-YIH WANG, New Taipei City (TW); YU-CHING HUANG, TAOYUAN COUNTY (TW); CHARN-YING CHEN, Taoyuan City (TW); HUNG-WEI LIU, Hsinchu City (TW); CHIH-MIN CHUANG, TAOYUAN COUNTY (TW); HOU-CHIN CHA, Taipei County (TW); FAN-HSUAN HSU, TAOYUAN COUNTY (TW); YEONG-DER LIN, Taoyuan County (TW)

(73) Assignee: INSTITUTE OF NUCLEAR ENERGY RESEARCH ATOMIC ENERGY COUNCIL, EXECUTIVE YUAN, TAOYUAN COUNTY (TW)

(21) Appl. No.: 13/967,710

(22) Filed: Aug. 15, 2013

(30) Foreign Application Priority Data
Oct. 26, 2012 (TW) 101139748

(51) Int. Cl. H01L 51/42; H01L 51/00

(52) U.S. Cl. CPC H01L 51/4253; H01L 51/0002
USPC 136/263; 252/500; 438/82

(57) ABSTRACT

A bulk heterojunction solar cell comprises an electron donor, an electron acceptor, and a multi-substituted fullerene derivative. The electron acceptor further comprises a nano-scale electron acceptor material, and a meso-scale mixture of electron donor/acceptor material. The multi-substituted fullerene derivative further comprises a single fullerene structure and a multi-substituted derivative connected to the single fullerene structure. The multi-substituted fullerene derivative is utilized to prevent the meso-scale mixture of electron donor/acceptor material from large-scale segregation of acceptor over a specific temperature after a specific period (thermally unstable state), thereby maintaining the thermal stability and the sizes of the nano-scale acceptor material and meso-scale mixture of electron donor/acceptor material. In the conventional knowledge, the large-scale segregation and corresponding degradation of power efficiency are cause mainly by the nano-scale acceptor material. The work shows the control and role of meso-scale structure is the most critical.

### FIELD OF THE INVENTION

The present invention relates to a photovoltaic technology, and more particularly, to a structure composed of a meso-scale mixture of electron donor/acceptor material that is used for improving thermal stability of bulk heterojunction polymer solar cells, and a related photovoltaic apparatus as well as a method for making the photovoltaic apparatus.

### BACKGROUND OF THE INVENTION

In recent years, bulk heterojunction (BHJ) polymer-fullerene blend films had been vastly applied in polymer solar cell and solar power industry. Generally, the BHJ structure of a polymer solar cell is composed of an electron donor and an electron acceptor, in which the electron donor can be made of a conjugated polymer of poly (3-hexylthiophene) (P3HT), and the electron acceptor is made of a mono-substituted fullerene derivative that is substantially a mono-substituted derivative connected to a fullerene structure. In general, the mono-substituted derivative can be a C-60 derivative, such as [6,6]-phenyl-C₆₁-butyric acid methyl ester (PCBM).

According to prior arts, a mixture of conjugated polymers and mono-substituted fullerene derivatives will be crystallized into a bi-continuous phase nano-scale structure for exciton separation and electron/hole transportation after being processed by a conventional annealing procedure or a solvent annealing procedure, and thus can be made into a conventional solar cell with BHJ structure. It is general that a bi-continuous phase with nano-scale structure is composed of nano-scale electron acceptors and conjugated polymers, and since the nano-scale electron acceptors after being heated by a high temperature (>110° C.) for a long period of time (>20 min) can aggregate or segregate into large-scale aggregation structure, the exciton separation efficiency of the BHJ structure is deteriorated accordingly and thus the power conversion efficiency (PCE) of the conventional solar cell is decreased, which can be referred as the thermal instability phenomenon, the original BHJ structure is inherently not in thermal equilibrium that can be easily induced into large-scale phase of segregation after being heated continuously for a long time. Therefore, there are already many techniques being developed for enhancing its thermal stability, and the followings are some examples:

(1) The formation of large-scale electron acceptor aggregations or phase segregation can be suppressed for maintaining good thermal stability by reducing the regioregularity of the polymers or by modifying its main chain so as to reduce the crystallization driving force.

(2) The thermal stability can be controlled by adopting polymers with high glass transition temperature as electron donors.

(3) The large-scale diffusion in electron acceptors can be restricted by the formation of a large polymer network in a cross-link manner.

(4) The compatibility between electron donors and electron acceptors can be improved by the adding of fullerene derivatives of different function groups to be used as compatibilizers, and thereby, the formation of large-scale electron donor aggregations can be suppressed even when being heated by a high temperature for a long period of time.

(5) The thermal stability of the BHJ structure can be improved by the adding of copolymers to be used as additives.

(6) The formation of large-scale electron acceptor aggregations or phase segregation can be suppressed by substituting a portion of those conventional electron acceptors with amorphous fullerene derivatives.

Although the formation of large-scale electron donor aggregations or phase segregation can be suppressed for improving thermal stability by the aforesaid techniques, there are still new problems arising from these aforesaid technique that can not be avoided as following:

(1) The crystallization of the low-regioregularity polymer electron donors can be interfered by the annealing process, whereas the reduction in crystallization can cause the charge mobility to decrease and thus the consequence power conversion efficiency is adversely affected. Moreover, even the effective interface area between electron donors and electron acceptors in the BHJ structure is reduced which is not good for charge separation.

(2) Although the high-temperature phase segregation can be prevented by the use of amorphous fullerene derivatives or modified fullerenes, the optimization in the nano-scale BHJ structure can be adversely affected by the amorphous electron acceptor, which is going to cause the charge transfer efficiency to decrease and thus the related power conversion efficiency is decreased.

(3) The solar cells can be easily subjected to a high temperature environment in a cell package or fabrication process, and thereby, the formation of large-scale electron acceptor aggregations can still be caused.

In summary, the key for a solar cell to have effective charge separation and high power conversion efficiency is its BHJ structure, which is a bi-continuous phase structure composed of nano-scale electron acceptor aggregations (or clusters) and electron donor crystallizations. However, the methods applied for improving thermal stability can simultaneously prevent the formation of nano-scale electron acceptor aggregations in the optimization of BHJ structure, which can be a dilemma. On the other hand, the application of those methods can also cause the manufacture cost to increase and the complexity of the manufacture process to increase as well.

### SUMMARY OF THE INVENTION

The primary object of the present invention is to provide a bulk heterojunction structure for improving thermal stability of a solar cell with keeping good power conversion efficiency, and the structure can be a multi-substituted fullerene derivative composed of: a fullerene structure and a multi-substituted derivatives connected to the fullerene structure, that is used for controlling the size of a meso-scale mixture of electron donor/acceptor material while preventing the nano-scale electron acceptor aggregates (clusters) from further aggregating into large-scale aggregations after being heated after being heated by a high temperature (>110° C.) for a long period of time (>20 min), and thereby, the thermal stability of solar cells with keeping high-performance and nano-scale BHJ structure is improved. Therefore, the “thermal instability” that is the main reason causing conventional polymer solar cells with BHJ structure to deteriorate after operating in high temperature for a long of time can be resolved, i.e. there will be no large-scale electron acceptor aggregations being generated to cause the performance of polymer solar cell to drop rapidly.

Another object of the invention is to provide a method for optimizing the formation of a BHJ structure with maximum efficiency while simultaneously enhancing the thermal stability of the optimized BHJ structure, and thereby, the cost of manufacture can be reduced as the manufacture process is simplified.

In an exemplary embodiment, the present invention provides a optimum structure for improving thermal stability of bulk heterojunction solar cells, which comprises: an electron donor; an electron acceptor, composed of a nano-scale electron acceptor material (a form of aggregation or clusters) , and a meso-scale mixture of electron donor/acceptor material (i.e., a meso-scale donor/acceptor structure); and a multi-substituted fullerene derivative, composed of a first fullerene structure and a multi-substituted derivative connected to the first fullerene structure, wherein, the multi-substituted fullerene derivative is utilized to prevent the meso-scale mixture of electron donor/acceptor material (meso-scale donor/acceptor structure) from segregation over a specific temperature after a long period, thereby maintaining the thermal stability and the sizes of the nano-scale acceptor clusters and meso-scale mixture of electron donor/acceptor materials (structures).

In another embodiment, the present invention further provides a bulk heterojunction polymer photovoltaic apparatus, which comprises: a photo active layer (i.e., photoelectric conversion layer), for converting an incident beam into a hole-electron pairs; with composition of an electron donor material; an electron acceptor material, composed of a nano-scale electron acceptor material (a form of aggregation or cluster), and a meso-scale mixture of electron donor/acceptor material (a meso-scale structure): and a multi-substituted fullerene derivative, composed of a first fullerene structure and a multi-substituted derivative connected to the first fullerene structure, and the multi-substituted fullerene derivative being provided and utilized to prevent the meso-scale mixture of electron donor/acceptor material (or structure) from segregation over a specific temperature after a specific period, thereby maintaining the thermal stability and the sizes of the nano-scale acceptor and meso-scale mixture of electron donor/acceptor materials (structures); two electrodes, being a first electrode and a second electrode arranged respectively connected to two sides of the photoactive layer while enabling the first electrode to be used for conducting holes and the second electrode to be used for conducting electrons.

In another embodiment, the present invention further provides a method for making bulk heterojunction photovoltaic apparatus, which comprises the steps of: providing a solution of photoelectric material, while the solution of photoelectric material comprises: a photoelectric conversion layer, for converting an incident beam into a plurality of hole-electron pairs; further comprising; an electron donor; an electron acceptor, composed of a nano-scale electron acceptor material (or clusters), and a meso-scale mixture of electron donor/acceptor material (or structure); and a multi-substituted fullerene derivative, composed of a first fullerene structure and a multi-substituted derivative connected to the first fullerene structure, whereas the multi-substituted fullerene derivative being provided and utilized to prevent the meso-scale mixture of electron donor/acceptor material from large-scale segregation over a specific temperature after a specific period, thereby maintaining the thermal stability and the sizes of the nano-scale acceptor material and meso-scale mixture of electron donor/acceptor material; coating the solution of photoelectric material on a first electrode so as to form a photoelectric conversion layer; and forming a second electrode on the photoelectric conversion layer.

Further scope of applicability of the present application will become more apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention and wherein:

FIG. 1 is a schematic diagram showing a photovoltaic apparatus (polymer solar cell) of the present invention.

FIG. 2 is a partly enlarged view of a photoactive layer (i.e., photoelectric conversion layer) of the present invention.

FIG. 3 is a schematic diagram showing a mono-substituted fullerene derivative according to an embodiment of the present invention.

FIG. 4 is a schematic diagram showing a multi-substituted fullerene derivative according to an embodiment of the present invention.

FIG. 5 is a flow chart depicting steps performed in a method for making bulk heterojunction photovoltaic apparatus (polymer solar cell) according to the present invention.

FIG. 6 is a chart depicting the relationship between anneal time and power conversion efficiency for a photoactive layer composed of multi-substituted fullerene derivative and other photoactive layer without multi-substituted fullerene derivative.

### DESCRIPTION OF THE EXEMPLARY EMBODIMENTS

For your esteemed members of reviewing committee to further understand and recognize the fulfilled functions and structural characteristics of the invention, several exemplary embodiments cooperating with detailed description are presented as the follows.

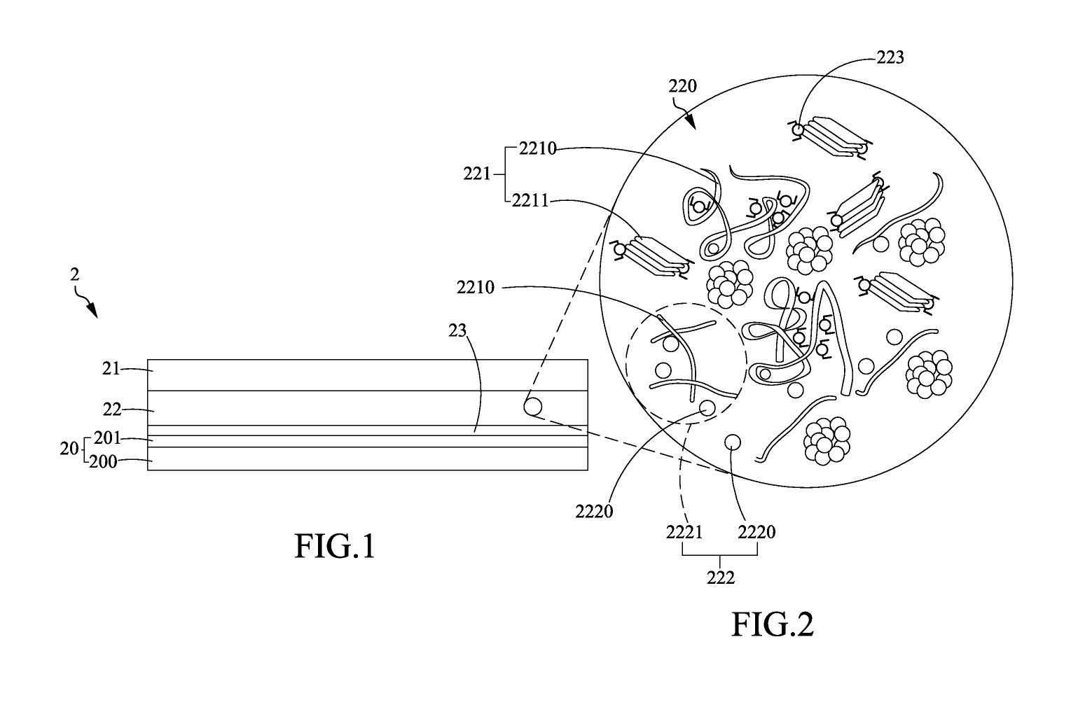

Please refer to FIG. 1, which a schematic diagram showing a photovoltaic apparatus (polymer solar cell) of the present invention. In this embodiment, the photovoltaic apparatus 2 comprises: a first electrode 20, a second electrode 21, and a photoactive layer (photoelectric conversion layer) 22 that is sandwiched between the first electrode 20 and the second electrode 21 for converting an incident beam into a plurality of hole-electron pairs. In this embodiment, the first electrode 20 is a transparent electrode that is formed with a substrate 200 and a conductive layer 201 disposed on the substrate 200. In addition, the substrate 200 is made of a transparent material, such as glass and plastic; and the conductive layer 201 can be made of a transparent conductive material, such as ITO, AZO, and ZnO, but is not limited thereby. In this embodiment, the conductive layer 201 is made of ITO. As shown in FIG. 1, there is further a hole transport layer 23 sandwiched between the first electrode 20 and the photoelectric conversion layer 22 that is used for transporting holes to the first electrode 20 and can be made of a P-type organic polymer or a P-type semiconductor material. In this embodiment, the hole transport layer 23 is made of PEDOT:PSS, but is not limited thereby. It is noted that the second electrode 21 that is disposed on the photoelectric conversion layer 22 can be a transparent unit similar to the aforesaid first electrode 20 in structure, or it can be an opaque electrode that is made of a conductive metal, such as Al, or AL/Ca. In this embodiment, the second electrode 21 is an Al/Ca electrode.

Please refer to FIG. 2, which is a partly enlarged view of a photoelectric conversion layer of the present invention. As shown in FIG. 2, the photoelectric conversion layer 22 is made of a bulk heterojunction material (structure) 220, whereas the bulk heterojunction material (structure) 220 is composed of: an electron donor 221, an electron acceptor 222 and a multi-substituted fullerene derivative 223. The electron donor 221 is a conjugated polymer and in this embodiment, the conjugated polymer can be a material selected from the group consisting of: poly (3-hexylthiophene) (P3HT) and the derivatives thereof. In this embodiment, the electron donor 221 can further include amorphous materials and crystal materials. Taking the P3HT for example, the electron donor 221 includes amorphous P3HT 2210 and P3HT crystal 2211.

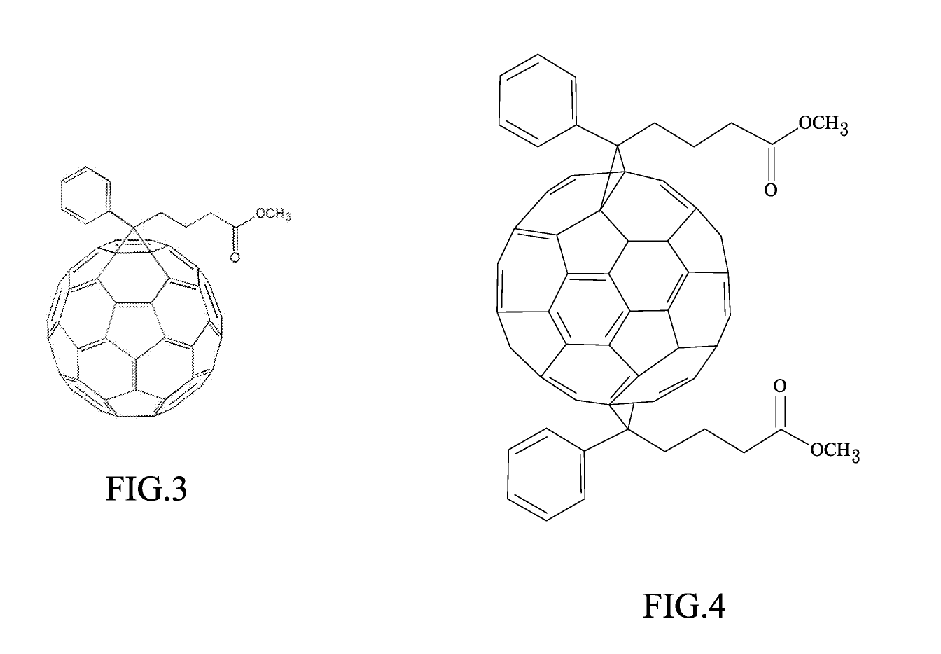

Moreover, the electron acceptor 222 is composed of a nano-scale electron acceptor material (a form of aggregation or cluster) 2220 and a meso-scale mixture of electron donor/acceptor material (or structure) 2221, whereas the mixture of electron donor/acceptor material 2221 is substantially the blending of the nano-scale electron acceptor material (cluster or even molecule) 2220 with the amorphous electron donor 2210. In this embodiment, the mixture of electron donor/acceptor material 2221 is formed by mixing the nano-scale electron acceptor material (cluster or even molecule) 2220 with amorphous P3HT 2210, and wherein, the nano-scale electron acceptor material 2220 can be a mono-substituted fullerene derivative that is composed of a fullerene structure and a mono-substituted derivative connecting to the fullerene structure. It is noted that fullerene structure is a matter selected from the group consisting of: C-60 molecule, C-70 molecule and C-84 molecule. In this embodiment, the mono-substituted derivative is a C-60 derivative, such as [6,6]-phenyl-C₆₁-butyric acid methyl ester (PCBM), as shown in FIG. 3. In addition, in this embodiment, the nano-scale is a size defined to be smaller than 20 nm; and the meso-scale is a size defined to be ranged between 20 nm and 300 nm.

The multi-substituted fullerene derivative 223 is substantially composed of a fullerene structure and a multi-substituted derivative connecting to the fullerene structure. Similarly, the fullerene structure is a matter selected from the group consisting of: C-60 molecule, C-70 molecule and C-84 molecule. In this embodiment, the multi-substituted derivative is a bi-substituted derivative, but is not limited thereby and can be a tris-substituted derivative or a tetrakis-substituted derivative, and so on. The multi-substituted fullerene derivative in this embodiment is bis-PCBM, as shown in FIG. 4, whereas the weight percentage of the bis-PCBM in the total amount of fullerene derivatives (i.e., PCBM+bis-PCBM) is ranged between 4 wt %˜17 wt %, i.e. P3HT/PCBM:xbis-PCBM (x=4˜17 wt %) for the photoactive layer material. It is noted that the multi-substituted fullerene derivative 223 is utilized to prevent the meso-scale mixture of electron donor/acceptor material (structure) from large-scale segregation of acceptor material 222 over a specific temperature after a specific period, thereby maintaining the thermal stability and the sizes of the nanoscale acceptor material 2220 and meso-scale mixture of electron donor/acceptor material 2221. In this embodiment, the heating of the photovoltaic apparatus over the specific temperature for the specific period is defined to be a condition selected from the group consisting of: heating the photovoltaic apparatus by a temperature higher than 110° C. for more than 30 min; and heating the photovoltaic apparatus by a temperature lower than 100° C. for more than 5 hr.

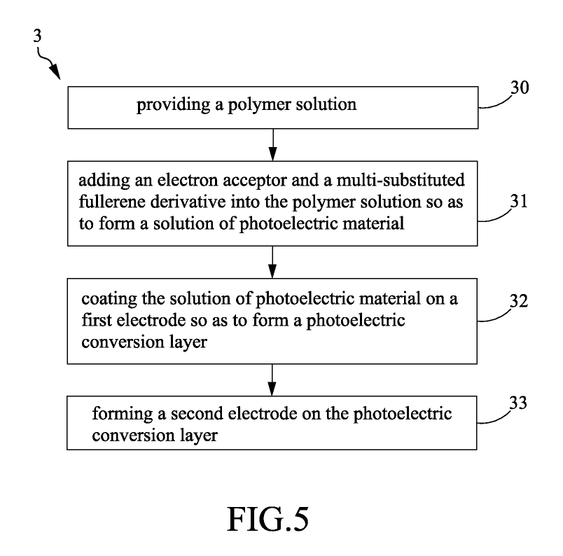

Please refer to FIG. 5, which is a flow chart depicting steps performed in a method for making bulk heterojunction photovoltaic apparatus according to the present invention. As shown in FIG. 5, the method for making bulk heterojunction photovoltaic apparatus 3 starts from the step 30. At step 30, a polymer solution is provided to be used as an electron donor, and then the flow proceeds to step 31. In this embodiment, the polymer contained in the polymer solution is a conjugated polymer, such as poly (3-hexylthiophene) (P3HT) or the derivatives thereof. At step 31, an electron acceptor that is composed of a nano-scale electron acceptor material, and a meso-scale mixture of electron donor/acceptor material, and a multi-substituted fullerene derivative that is composed of a first fullerene structure and a multi-substituted derivative connected to the first fullerene structure are added into the polymer solution so as to form a solution of photoelectric material, whereas the multi-substituted fullerene derivative being provided and utilized to prevent the meso-scale mixture of electron donor/acceptor material 2221 and the nano-scale acceptor material 2220 from large-scale segregation of acceptor material 222 over a specific temperature after a specific period, thereby maintaining the thermal stability and the sizes of the nano-scale material 2220 and meso-scale mixture of electron donor/acceptor material 2221; and then the flow proceeds to step 32. Similarly, the electron donor can further include amorphous materials and crystal materials, and also the multi-substituted fullerene derivative is composed of a fullerene structure and a multi-substituted derivative connecting to the fullerene structure. Since the electron donor and the multi-substituted fullerene derivative are the same in structure as those described in FIG. 2, and thus will not be described further herein. In addition, in this embodiment, the nano-scale is a size defined to be smaller than 20 nm; and the meso-scale is a size defined to be ranged between 20 nm and 300 nm; and the weight percentage of the multi-substituted fullerene derivative in the total amount of fullerene derivatives (PCBM+bis-PCBM) is ranged between 4 wt %˜17 wt %.

At step 32, the solution of photoelectric material that is achieved at the step 31 is coated on a first electrode into a photoactive layer (photoelectric conversion layer); and then the flow proceeds to step 33. It is noted that the coating of the solution of photoelectric material can be performed by a means of spin coating, a means of spray coating or a means of blade coating. In this embodiment, a means of spin coating is used. At step 33, a second electrode is formed on the photoelectric conversion layer. The photovoltaic apparatus that is produced by the method 3 is the one shown in FIG. 1.

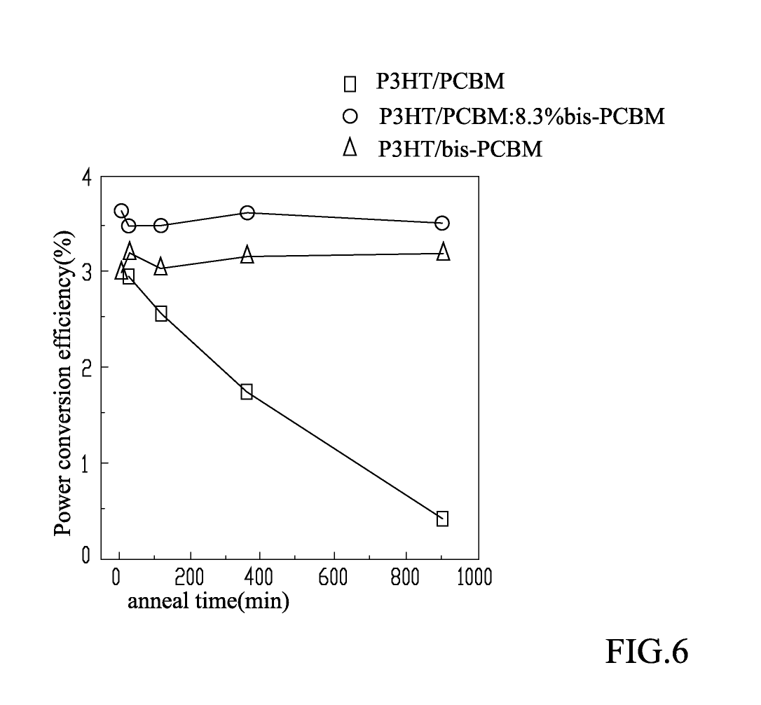

Please refer FIG. 6 is a chart depicting the relationship between annealing time (at high temperature of 150° C.) and power conversion efficiency for a photoelectric conversion layer composed of multi-substituted fullerene derivative and other photoelectric conversion layers without multi-substituted fullerene derivative. In FIG. 6, the curve marked by the rectangular icons represents the relationship of PCE and annealing time for a photoelectric conversion layer made of P3HT/PCBM; the curve marked by the circular icons represents the relationship of PCE and annealing time for a photoelectric conversion layer made of P3HT/PCBM:8.3%bis-PCBM; and the curve marked by the triangular icons represents the relationship of PCE and annealing time for a photoelectric conversion layer made of P3HT/bis-PCBM. As shown in FIG. 6, the PCE of the photoelectric conversion layer fully containing bi-substituted fullerene derivative (bis-PCBM) is able to maintain at a specific efficiency during a high-temperature annealing process of about 900 min (i.e., keeping good thermal stability but having a lower conversion efficiency). However, for those photoelectric conversion layers without bis-PCBM, their PCE is sharply dropping with the progress of the annealing process (poor thermal stability). The photoelectric conversion layer partly containing bi-substituted fullerene derivative (P3HT/PCBM:8.3%bis-PCBM) has the good thermal stability and high PCE. On the other hand, the structural analysis for three kinds of photoactive layers at different annealing times was performed using synchrotron radiation scattering experiment and optical microscopic observation. The degradation in PCE of P3HT/PCBM layer with annealing time is caused by the growth of meso-scale P3HT/PCBM domains and simultaneous aggregation into large-scale domains (i.e., thermally unstable structure). In contrast, the photoactive layers of P3HT/PCBM:8.3%bis-PCBM has a thermally stable meso-scale P3HT/PCBM:bisPCBM domain and no large-scale aggregation. The photoactive layer of P3HT/bis-PCBM also has a thermally stable meso-scale P3HT/bisPCBM domain and no large-scale aggregation. So, the active layers containing bis-PCBM have good thermal stability. However, the photoactive layer of P3HT/bis-PCBM has much less nano-scale bisPCBM clusters, leading the lower efficiency. The nano-scale acceptor structure in the active layers are basically stable (not change in size during heating for long time). In the conventional knowledge, the large-scale segregation is cause by the nano-scale acceptor material. We firstly report that the control and role of the meso-scale acceptor/donor structure is the most critical on the thermal stability.

To sum up, the present invention is provides a structure for improving thermal stability of a bulk heterojunction polymer solar cell, and the structure can be a multi-substituted fullerene derivative, that is used for controlling the size of a meso-scale mixture of electron donor/acceptor material while preventing both the nano-scale electron acceptors and meso-scale electron donor/acceptor material from aggregating into large-scale aggregations after being heated after being heated by a high temperature (>110° C.) for a long period of time (>20 min), and thereby, the thermal stability of solar cells with BHJ structure is improved. Therefore, the “thermal instability” that is the main reason causing conventional polymer solar cells of BHJ structure to deteriorate after operating at high temperature for a long time can be resolved, i.e. there will be no large-scale electron acceptor aggregations being generated to cause the solar cell performance to drop rapidly.

With respect to the above description then, it is to be realized that the optimum dimensional relationships for the parts of the invention, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present invention.

What is claimed is:

1. A structure for improving thermal stability of bulk heterojunction solar cells, comprising:
an electron donor;
an electron acceptor, composed of a nano-scale electron acceptor material (a form of aggregation or clusters), and a meso-scale mixture of electron donor/acceptor material (or structure); and
a multi-substituted fullerene derivative, composed of a first fullerene structure and a multi-substituted derivative connected to the first fullerene structure,
wherein, the multi-substituted fullerene derivative is utilized to prevent the meso-scale mixture of electron donor/acceptor material (structure) from a large-scale segregation of acceptor material over a specific temperature after a specific period, thereby maintaining the thermal stability and the sizes of the nano-scale acceptor material and meso-scale mixture of electron donor/acceptor material.

2. The structure of claim 1, wherein the electron donor is substantially a conjugated polymer.

3. The structure of claim 2, wherein the conjugated polymer is a material selected from the group consisting of: poly (3-hexylthiophene) (P3HT) and the derivatives thereof.

4. The structure of claim 1, wherein the electron acceptor is a mono-substituted fullerene derivative, and the mono-substituted fullerene derivative is composed of:
a second fullerene structure and a mono-substituted derivative connected to the second fullerene structure.

5. The structure of claim 4, wherein the second fullerene structure is a matter selected from the group consisting of: C-60 molecule, C-70 molecule and C-84 molecule.

6. The structure of claim 4, wherein the mono-substituted derivative is a C-60 derivative, such as [6,6]-phenyl-C₆₁-butyric acid methyl ester (PCBM).

7. The structure of claim 1, wherein the first fullerene structure is a matter selected from the group consisting of: C-60 molecule, C-70 molecule and C-84 molecule.

8. The structure of claim 1, wherein the multi-substituted fullerene derivative is bis-PCBM.

9. The structure of claim 8, wherein the weight percentage of the bis-PCBM in the total amount of fullerene derivatives used is ranged between 4 wt % and 17 wt %.

10. The structure of claim 1, wherein the meso-scale is a size defined to be ranged between 20 nm and 300 nm.

11. The structure of claim 1, wherein the nano-scale is a size defined to be smaller than 20 nm.

12. The structure of claim 1, wherein the heating of the photovoltaic apparatus over the specific temperature for the specific period is defined to be a condition selected from the group consisting of: heating the photovoltaic apparatus by a temperature higher than 110° C. for more than 30 min; and heating the photovoltaic apparatus by a temperature lower than 100° C. for more than 5 hr.

13. A bulk heterojunction photovoltaic apparatus, comprising:
a photoelectric conversion layer, for converting an incident beam into a plurality of hole-electron pairs; further comprising:
an electron donor;
an electron acceptor, composed of a nano-scale electron acceptor material, and a meso-scale mixture of electron donor/acceptor material; and
a multi-substituted fullerene derivative, composed of a first fullerene structure and a multi-substituted derivative connected to the first fullerene structure, and the multi-substituted fullerene derivative being provided and utilized to prevent the meso-scale mixture of electron donor/acceptor material from large-scale segregation over a specific temperature after a specific period (i.e., thermally unstable state), thereby maintaining the thermal stability and the sizes of the nano-scale acceptor material and meso-scale mixture of electron donor/acceptor material; and
two electrodes, being a first electrode and a second electrode arranged respectively connected to two sides of the photoelectric conversion layer while enabling the first electrode to be used for conducting holes and the second electrode to be used for conducting electrons.

14. The photovoltaic apparatus of claim 13, wherein the electron donor is substantially a conjugated polymer.

15. The photovoltaic apparatus of claim 14, wherein the conjugated polymer is a material selected from the group consisting of: poly (3-hexylthiophene) (P3HT) and the derivatives thereof.

16. The photovoltaic apparatus of claim 13, rein the electron acceptor is a mono-substituted fullerene derivative.

17. The photovoltaic apparatus of claim 16, wherein the fullerene structure in the mono-substituted fullerene derivative is a matter selected from the group consisting of: C-60 molecule, C-70 molecule and C-84 molecule.

18. The photovoltaic apparatus of claim 16, wherein the mono-substituted fullerene derivative is [6,6]-phenyl-C₆₁-butyric acid methyl ester (PCBM).

19. The photovoltaic apparatus of claim 16, wherein the first fullerene structure is a matter selected from the group consisting of: C-60 molecule, C-70 molecule and C-84 molecule.

20. The photovoltaic apparatus of claim 13, wherein the multi-substituted fullerene derivative is bis-PCBM.

21. The photovoltaic apparatus of claim 20, wherein the weight percentage of the bis-PCBM in the total amount of fullerene derivatives is ranged between 4 wt % and 17 wt %.

22. The photovoltaic apparatus of claim 13, wherein the meso-scale is a size defined to be ranged between 20 nm and 300 nm.

23. The photovoltaic apparatus of claim 13, wherein the nano-scale is a size defined to be smaller than 20 nm.

24. The photovoltaic apparatus of claim 13, wherein the heating of the photovoltaic apparatus over the specific temperature for the specific period is defined to be a condition selected from the group consisting of: heating the photovoltaic apparatus by a temperature higher than 110° C. for more than 30 min; and heating the photovoltaic apparatus by a temperature lower than 100° C. for more than 5 hr.

25. A method for making bulk heterojunction photovoltaic apparatus, comprising the steps of:
providing a solution of photoelectric material, while the solution of photoelectric material comprises: a photoelectric conversion layer, for converting an incident beam into a plurality of hole-electron pairs; further comprising: an electron donor; an electron acceptor, composed of a nano-scale electron acceptor material (a form of aggregation or cluster), and a meso-scale mixture of electron donor/acceptor material (or structure); and a multi-substituted fullerene derivative, composed of a first fullerene structure and a multi-substituted derivative connected to the first fullerene structure, whereas the multi-substituted fullerene derivative being provided and utilized to prevent the meso-scale mixture of electron donor/acceptor material from large-scale segregation over a specific temperature after a specific period, thereby maintaining the thermal stability and the sizes of the nano-scale acceptor material and meso-scale mixture of electron donor/acceptor material;
coating the solution of photoelectric material on a first electrode so as to form a photoelectric conversion layer; and
forming a second electrode on the photoelectric conversion layer.

26. The method of claim 25, wherein the electron donor is substantially a conjugated polymer.

27. The method of claim 26, wherein the conjugated polymer is a material selected from the group consisting of: poly (3-hexylthiophene) (P3HT) and the derivatives thereof.

28. The method of claim 25, wherein the electron acceptor is a mono-substituted fullerene derivative.

29. The method of claim 25, wherein the fullerene structure in the mono-substituted fullerene derivative is a matter selected from the group consisting of: C-60 molecule, C-70 molecule and C-84 molecule.

30. The method of claim 25, wherein the mono-substituted derivative is a C-60 derivative, such as [6,6]-phenyl-C₆₁-butyric acid methyl ester (PCBM).

31. The method of claim 25, wherein the first fullerene structure is a matter selected from the group consisting of: C-60 molecule, C-70 molecule and C-84 molecule.

32. The method of claim 25, wherein the multi-substituted fullerene derivative is bis-PCBM.

33. The method of claim 32, wherein the weight percentage of the bis-PCBM in the total amount of fullerene derivatives is ranged between 4 wt % and 17 wt %.

34. The method of claim 25, wherein he meso-scale is a size defined to be ranged between 20 nm and 300 nm.

35. The method of claim 25, wherein the nano-scale is a size defined o be smaller than 20 nm.

36. The method of claim 25, wherein the heating of the photovoltaic apparatus over the specific temperature for the specific period is defined to be a condition selected from the group consisting of: heating the photovoltaic apparatus by a temperature higher than 110° C. for more than 30 min; and heating the photovoltaic apparatus by a temperature lower than 100° C. for more than 5 hr.
